(19) United States
(12) Patent Application Publication
(10) Pub. No.: US 2007/0166858 A1
(43) Pub. Date: Jul. 19, 2007

(54) METHOD OF MANUFACTURING VERTICAL INORGANIC ALIGNMENT LAYER AND LIQUID CRYSTAL DISPLAY HAVING THE VERTICAL INORGANIC ALIGNMENT LAYER

(76) Inventors: Soon-Joon Rho, Suwon-si (KR); Duck-Jong Suh, Seoul (KR)

Correspondence Address: F. CHAU & ASSOCIATES, LLC, 130 WOODBURY ROAD, WOODBURY, NY, 11797, US

(21) Appl. No.: 11/623,211

(22) Filed: Jan. 15, 2007

(30) Foreign Application Priority Data
Jan. 16, 2006 (KR) 10-2006-004445
Nov. 30, 2006 (KR) 10-2006-119981

(51) Int. Cl. H01L 21/00

(52) U.S. Cl. 438/30

(57) ABSTRACT

In a method of manufacturing a vertical inorganic alignment layer and a liquid crystal display having the vertical inorganic alignment layer, a plasma power is applied to a plasma generating member attached to an outside of a reactor. When a process substrate to which a back-bias voltage and heat are applied is loaded into the reactor, a reaction gas is injected into the reactor. Then, when a frequency of the plasma power is controlled, the vertical inorganic alignment layer having a resistivity of about 10¹⁰ ohms-cm to about 10¹⁵ ohms-cm and a vertical aligning property is formed on the process substrate. Thus, the liquid crystal display may prevent deterioration of display quality thereof due to an electrostatic field.

### CROSS-REFERENCE TO RELATED APPLICATION

This application relies for priority upon Korean Patent Application Nos. 2006-04445 filed on Jan. 16, 2006 and 2006-119981 filed on Nov. 30, 2006, the contents of which are herein incorporated by references in their entireties.

### BACKGROUND OF THE INVENTION

1. Technical Field

The present disclosure relates to a liquid crystal display. More particularly, the present disclosure relates to a liquid crystal display having a vertical inorganic alignment layer and a method of manufacturing the vertical inorganic alignment layer.

2. Discussion of Related Art

In general, a liquid crystal display includes an array substrate, a color filter substrate and a liquid crystal layer. The liquid crystal layer includes liquid crystal molecules and is interposed between the array substrate and the color filter substrate. The array substrate and the color filter substrate include an alignment layer formed on their surfaces in order to align the liquid crystal molecules of the liquid crystal layer in a certain direction.

Broadly, the alignment layer is classified as either a horizontal alignment layer or a vertical alignment layer. The horizontal alignment layer allows the liquid crystal molecules to be aligned in a direction substantially parallel to the surfaces of the substrates when no power is applied to the liquid crystal layer. On the contrary, the vertical alignment layer allows the liquid crystal molecules to be inclined in a perpendicular direction with respect to the surfaces of the substrates when no power is applied to the liquid crystal layer.

The horizontal and vertical alignment layers generally include a polyimide-containing material. More specifically, the vertical alignment layer is completed through baking and curing processes after printing the polyimide-containing material on a process substrate. Recently, in order to reduce a manufacturing cost, a size of the process substrate on which the vertical alignment layer is formed has been gradually increased. When the size of the process substrate increases, however, the polyimide-containing material is not printed on the process substrate uniformly.

### SUMMARY OF THE INVENTION

Exemplary embodiments of the present invention provide a method of manufacturing a vertical inorganic alignment layer.

Exemplary embodiments of the present invention also provide a liquid crystal display having the vertical inorganic alignment layer formed by using the above method.

In an exemplary embodiment of the present invention, a method of manufacturing a vertical inorganic alignment layer is provided as follows. When a plasma power is applied to a plasma generating member attached to an outside of a reactor and a process substrate is loaded into the reactor, to which a back-bias voltage and a heat are applied, a reaction gas is injected into the reactor. The frequency of the plasma power is controlled, so that a vertical inorganic alignment layer is formed onto the process substrate. The vertical inorganic alignment layer has a resistivity of about 10¹⁰ ohms-cm to about 10¹⁵ ohms-cm and has a vertical aligning property.

In an exemplary embodiment of the present invention, a method of manufacturing a vertical inorganic alignment layer is provided as follows. A process substrate is loaded into a reactor in which a target having an inorganic material is received, and a plasma power is applied to a plasma generating member attached to an outside of the reactor. When an inert gas is injected into the reactor and a frequency of the plasma power is controlled, a vertical inorganic alignment layer having a resistivity of about 10¹⁰ ohms-cm to about 10¹⁵ ohms-cm and having a vertical aligning property is formed onto the process substrate.

According to an exemplary embodiment of the present invention, a method of manufacturing a liquid crystal display is provided as follows. A first display substrate having a first base substrate, a common electrode formed on the first base substrate, and a first vertical inorganic alignment layer formed on the common electrode is fabricated. A second display substrate having a second base substrate, a pixel electrode formed on the second base substrate, and a second vertical inorganic alignment layer formed on the pixel electrode is fabricated. Then, a liquid crystal layer is formed between the first display substrate and the second display substrate, and the liquid crystal layer has a resistivity that is equal to those of the first and second vertical inorganic alignment layers.

In an exemplary embodiment of the present invention, a liquid crystal display includes a first display substrate, a second display substrate and a liquid crystal layer. The first display substrate includes a first base substrate, a common electrode formed on the first base substrate, and a first vertical inorganic alignment layer formed on the common electrode. The second display substrate includes a second base substrate, a pixel electrode formed on the second base substrate, and a second vertical inorganic alignment layer formed on the pixel electrode. The liquid crystal layer is interposed between the first display substrate and the second display substrate, and the liquid crystal layer has a resistivity that is equal to those of the first and second vertical inorganic alignment layers.

According to the exemplary embodiment, the vertical inorganic alignment layer has same resistivity as that of the liquid crystal layer, and the resistivity of the vertical inorganic alignment layer is controlled depending on the frequency of the plasma power applied to the target while the vertical inorganic alignment layer is formed. Thus, the liquid crystal layer may prevent deterioration of display quality due to an electrostatic field.

### BRIEF DESCRIPTION OF THE DRAWINGS

Exemplary embodiments of the present invention will be understood in more detail from the following descriptions taken in conjunction with the accompanying drawings wherein:

FIG. 1 is a sectional view illustrating a process of forming a vertical inorganic alignment layer according to an exemplary embodiment of the present invention;
FIG. 2 is a graph illustrating the resistivity of the vertical inorganic alignment layer with respect to a frequency of a plasma power;
FIG. 3 is a sectional view illustrating a process of forming a vertical inorganic alignment layer according to an exemplary embodiment of the present invention;

FIG. 4 is a plan view showing a PVA (patterned vertical alignment) mode liquid crystal display according to an exemplary embodiment of the present invention; and

FIG. 5 is a cross-sectional view taken along a line I-I′ of FIG. 4.

### DESCRIPTION OF EXEMPLARY EMBODIMENTS

Hereinafter, exemplary embodiments of the present invention will be explained in detail with reference to the accompanying drawings.

FIG. 1 is a sectional view illustrating a process of forming a vertical inorganic alignment layer according to an exemplary embodiment of the present invention.

Referring to FIG. 1, a process substrate 40 heated to a predetermined temperature is loaded in a reactor 50. The reactor 50 includes a plasma generating member 51 attached to an outside thereof, and a plasma power is applied to the plasma generating member 51. In the present embodiment, the plasma generating member 51 attached to an outside thereof, and a plasma power is applied to the plasma generating member 51. In the present embodiment, the plasma generating member 51 includes a coil, and a back-bias voltage is applied to the process substrate 30. In an example of the present embodiment, the back-bias voltage has 0 voltage.

A silicon-containing gas and an oxygen-containing gas are injected into the reactor 50. The silicon-containing gas includes a silane (SiH₄) gas, and the oxygen-containing gas includes a nitrous oxide (N₂O) gas.

The silicon-containing gas and the oxygen-containing gas react with each other on the process substrate 30, so that a vertical inorganic alignment layer 40, which includes silicon oxide (SiOx) having a vertical aligning property, is formed on the process substrate 30.

When the plasma power is controlled to have a frequency of about 10¹ Hz to about 10⁵ Hz, the vertical inorganic alignment layer 40 has a resistivity (ρ) of about 10¹⁰ ohms-cm to about 10¹⁵ ohms-cm (Ω cm). As an example, in the exemplary embodiment the vertical inorganic alignment layer 40 has a resistivity of about 10¹⁰ ohms-cm.

FIG. 2 is a graph illustrating the resistivity of the vertical inorganic alignment layer with respect to the frequency of the plasma power. In FIG. 2, the X and Y axes indicate the frequency (Hz) and the resistivity (Ω cm), respectively. Also, a first line G1 represents that the process substrate 30 is heated to a temperature of about 400 Celsius, and a second line G2 represents that the process substrate 30 is not heated.

Referring to FIG. 2, the resistivity (ρ) of the vertical inorganic alignment layer 45 decreases as the frequency of the plasma power increases. As shown by the first and second lines G1 and G2, when the frequency of the plasma power is maintained in a range of about 10¹ Hz to about 10⁵ Hz, the vertical inorganic alignment layer 40 having the resistivity (ρ) of about 10¹⁵ ohms-cm to about 10¹³ ohms-cm is formed.

As will be seen from FIG. 2, however, the heating temperature for the process substrate 30 does not have much influence on the resistivity (ρ) of the vertical inorganic alignment layer 40. Thus, in the exemplary embodiments of the present invention, the resistivity (ρ) of the vertical inorganic alignment layer 40 may be controlled by using the frequency of the plasma power.

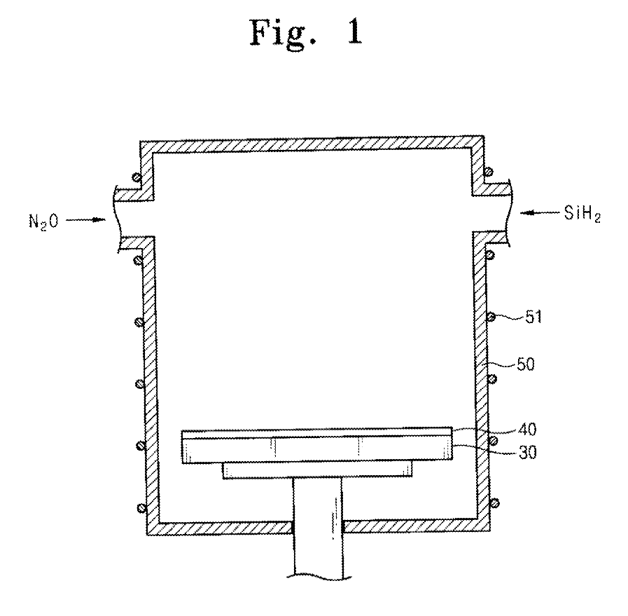

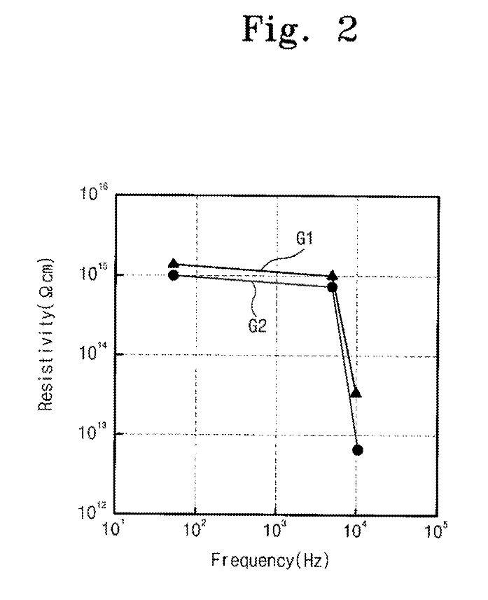

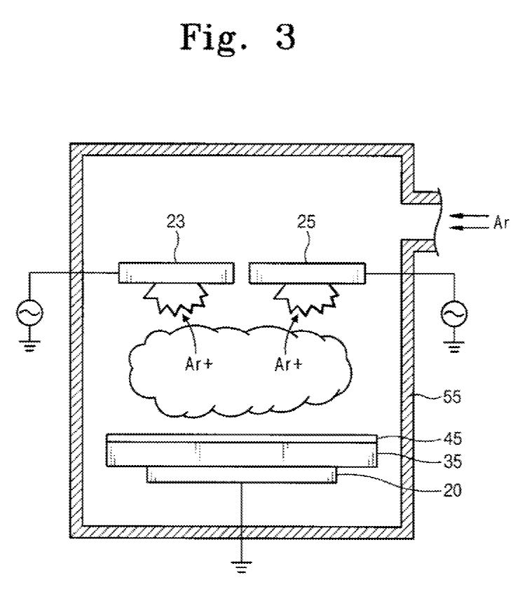

FIG. 3 is a sectional view illustrating a process of forming a vertical inorganic alignment layer according to an exemplary embodiment of the present invention.

Referring to FIG. 3, a support 20, a first target 23 and a second target 25 are received in a reactor 55 maintained at a vacuum state. The support 20 supports a process substrate 35, and the first and second targets 23 and 25 include a silicon-containing material and an oxide material, respectively. The second target 25 may be a carbide material.

The process substrate 35 is transferred into the reactor 55 and disposed on the support 20. In the exemplary embodiment, the process substrate 35 may be heated to the temperature of about 400 Celsius.

Then, a back-bias voltage is applied to the process substrate 35, and a first plasma power and a second plasma power are applied to the first and second targets 23 and 25, respectively. In the exemplary embodiment, the first and second plasma powers have a frequency of about 10¹ Hz to about 10⁵ Hz, and the back-bias voltage has 0 voltage.

An inert gas, for example, an argon (Ar) gas, is injected into the reactor 55. The argon (Ar) gas collides with electrons discharged from the first and second targets 23 and 25 and is excited to argon ions (Ar+), and the argon ions (Ar+) collide with the first and second targets 23 and 25. When the argon ions (Ar+) collide with the first and second targets 23 and 25, silicon atoms and oxygen atoms are discharged from the first and second targets 23 and 25, respectively. The discharged silicon atoms and oxygen atoms are coupled to each other and coated on the process substrate 35 as a thin film.

Thus, a vertical inorganic alignment layer 45 that includes the silicon oxide (SiOx) having the vertical aligning property is formed on the process substrate 35 in the present embodiment, the vertical inorganic alignment layer 45 has the resistivity (ρ) of about 10¹⁰ ohms-cm to about 10¹⁵ ohms-cm.

In the case that the second target 25 includes the carbide material, however, the vertical inorganic alignment layer 45 also includes silicon carbide (SiCx).

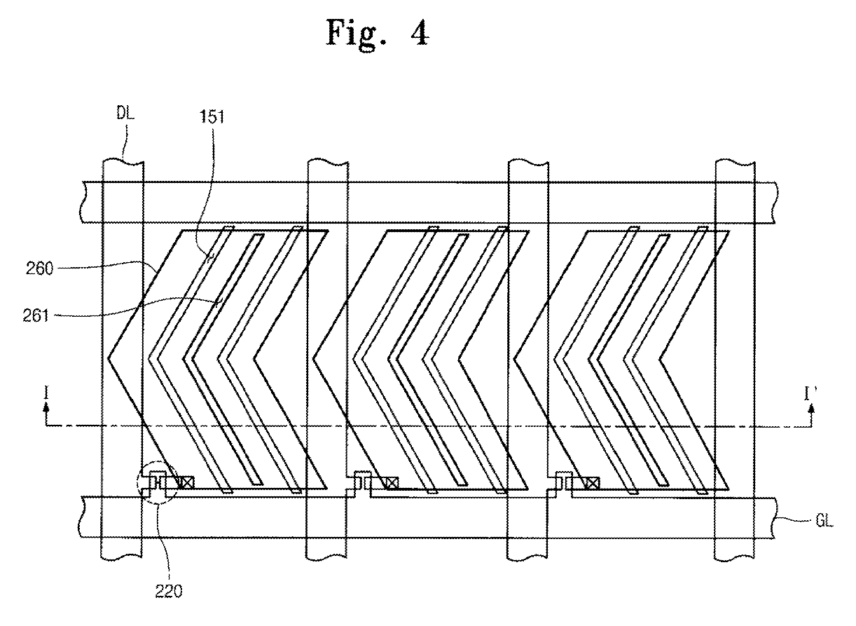

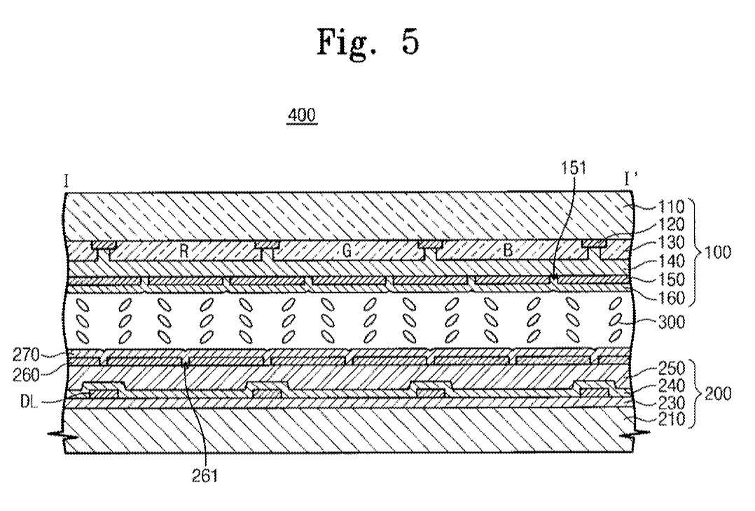

FIG. 4 is a plan view showing a PVA (patterned vertical alignment) mode liquid crystal display according to an exemplary embodiment of the present invention, and FIG. 5 is a cross-sectional view taken along a line I-I′ of FIG. 4.

Referring to FIGS. 4 and 5, a PVA mode liquid crystal display 400 includes a color filter substrate 100, an array substrate 200 facing the color filter substrate 100 and a liquid crystal 300 interposed between the color filter substrate 100 and the array substrate 200.

The color filter substrate 100 includes a first base substrate 110, a black matrix 120, a color filter layer 130, a common electrode 150, and a first vertical inorganic alignment layer 160.

The black matrix 120 is formed on the first base substrate 110, and the color filter layer 130 includes red, green and blue (RGB) color pixels. The color filter layer 130 is formed on the first base substrate 110 that also has the black matrix 120 formed thereon.

An over-coating layer 140 is further formed on the black matrix 120 and the color filter layer 130. The over-coating layer 140 is a leveling layer that reduces a step-difference between the black matrix 120 and the color filter layer 130 and servers to planarize the surface of the color filter substrate 100.

The common electrode 150 is formed on the over-coating layer 140. The common electrode 150 is provided with a first opening 151 formed therethrough to expose the over-coating layer 140. The first opening 151 has a V shape, as seen in the plan view of FIG. 4.

In the exemplary embodiment, the first vertical inorganic alignment layer 160 includes the silicon oxide (SiOx) and is formed on the common electrode 150 through the process as illustrated in FIG. 1. The first vertical inorganic alignment layer 45 has the resistivity (ρ) of about 10¹⁰ ohms-cm to about 10¹⁵ ohms-cm.

The array substrate 200 includes a second base substrate 210, a gate line GL, a data line DL, a thin film transistor 220, as shown in FIG. 4, a pixel electrode 260 and a second vertical inorganic alignment layer 270.

The gate line GL and the data line DL are formed on the second base substrate 210 and are extended in respective directions to allow the gate and data lines GL and DL to be intersected with each other. The gate line GL and the data line DL are electrically insulated form each other by a gate insulation layer 230 and receive a gate signal and a data signal, respectively.

The thin film transistor 220 and the pixel electrode 260 are formed in a pixel area defined by the gate line GL and the data line DL. The thin film transistor 220 is electrically connected to the gate line GL and the data line DL crossing each other. More specifically, the thin film transistor 220 includes a gate electrode electrically connected to the gate line GL, a source electrode electrically connected to the data line DL and a drain electrode electrically connected to the pixel electrode 260. Thus, the thin film transistor 220 applies the data signal to the pixel electrode 260 in response to the gate signal.

The pixel electrode 260 is angled to have a V shape, and an angled portion of the pixel electrode 260 is partially overlapped with the data line DL. The pixel electrode 260 is provided with a second opening 261 formed by removing a center portion thereof. The second opening 261 also has a V shape.

In the exemplary embodiment, the second opening 261 formed through the pixel electrode 260 is positioned between the first openings 151 formed through the common electrode 150. Thus, the pixel area of the liquid crystal display 400 is divided into plural domains by the first and second openings 151 and 261, each of which has the liquid crystal molecules aligned to different directions.

In the exemplary embodiment, the second vertical inorganic alignment layer 270 includes silicon oxide (SiOx) and is formed on the pixel electrode 260 through the process as illustrated in FIG. 1. The second vertical inorganic alignment layer 45 has the resistivity (ρ) of about 10¹⁰ ohms-cm to about 10¹⁵ ohms-cm.

When the array substrate 200 is completed, the liquid crystal is dropped on the array substrate 200. Then, the array substrate 200 on which the liquid crystal has been dropped is combined with the color filter substrate 100, thereby forming the liquid crystal layer 300 between the color filter substrate 100 and the array substrate 200. The liquid crystal molecules of the liquid crystal layer 300 are vertically aligned in a black display state by the first and second vertical inorganic alignment layers 160 and 270.

As an exemplary embodiment of the present invention, the liquid crystal layer 300 has the same resistivity as the resistivity of the first and second vertical inorganic alignment layers 160 and 270. Thus, the liquid crystal layer 300 has same capacitance as those of the first and second vertical inorganic alignment layers 160 and 270. Thus, the liquid crystal display 400 may prevent an electric charge from being charged between the liquid crystal layer 300 and the first vertical inorganic alignment layer 160 and between the liquid crystal layer 300 and the second vertical inorganic alignment layer 270, thereby preventing deterioration of display quality due to an electrostatic field.

Also, when an electric field is formed between the pixel electrode 260 and the common electrode 150 of the liquid crystal display 400, the liquid crystal molecules of the liquid crystal layer 300 are aligned to different directions in accordance with the domains. Thus, the liquid crystal display 400 may control light transmittance using the aligned liquid crystal molecules, to thereby improve a viewing angle of the liquid crystal display 400.

Although not shown in FIGS. 4 and 5, since the liquid crystal display 400 that uses the liquid crystal molecules is a non-emissive device, the liquid crystal display further includes a backlight assembly positioned at a rear side of the array substrate 200 to emit light. Thus, the liquid crystal display 400 displays an image using the light that is emitted from the backlight assembly (not shown) and has the light transmittance controlled by the liquid crystal layer 300.

According to the above-described exemplary embodiment, the vertical inorganic alignment layer has the same resistivity as that of the liquid crystal layer, and the resistivity of the vertical inorganic alignment layer is controlled depending on the frequency of the plasma power applied to the target while the vertical inorganic alignment layer is formed.

Thus, the liquid crystal display may prevent an electric charge from being formed between the liquid crystal layer and the first vertical inorganic alignment layer and between the liquid crystal layer and the second vertical inorganic alignment layer, thereby preventing deterioration of display quality due to an electrostatic field.

Although the exemplary embodiments of the present invention have been described, it is understood that the present invention should not be limited to these exemplary embodiments but various changes and modifications can be made by one ordinary skilled in the art within the spirit and scope of the present invention, as hereinafter claimed.

What is claimed is:

1. A method of manufacturing a vertical inorganic alignment layer, comprising:
applying a plasma power to a plasma generating member attached to an outside of a reactor;
loading a process substrate into the reactor, to which a back-bias voltage and heat are applied;
injecting a reaction gas into the reactor; and
controlling a frequency of the plasma power to form a vertical inorganic alignment layer onto the process substrate, the vertical inorganic alignment layer having a resistivity of about 10¹⁰ ohms-cm to about 10¹⁵ ohms-cm and a vertical aligning property.

2. The method of claim 1, wherein the vertical inorganic alignment layer has a resistivity of about 10¹⁰ ohms-cm.

3. The method of claim 1, wherein the plasma power has a frequency of about 10¹ Hz to about 10⁵ Hz.

4. The method of claim 1, wherein the reaction gas comprises a silicon-containing gas and an oxygen-containing gas, and the vertical inorganic alignment layer comprises a silicon oxide layer (SiOx).

5. A method of manufacturing a vertical inorganic alignment layer, comprising:
loading a process substrate into a reactor in which a target having an inorganic material is received;
applying a plasma power to a plasma generating member attached to an outside of the reactor;
injecting an inert gas into the reactor; and
controlling a frequency of the plasma power to form a vertical inorganic alignment layer onto the process substrate, the vertical inorganic alignment layer having a resistivity of about 10¹⁰ ohms-cm to about 10¹⁵ ohms-cm and a vertical aligning property.

6. The method of claim 5, wherein the vertical inorganic alignment layer comprises a silicon oxide layer (SiOx).

7. The method of claim 6, wherein the target comprises:
a first target having a silicon-containing material; and
a second target having an oxide material.

8. A method of manufacturing a liquid crystal display, comprising:
fabricating a first display substrate having a first base substrate, a common electrode formed on the first base substrate, and a first vertical inorganic alignment layer formed on the common electrode;
fabricating a second display substrate having a second base substrate, a pixel electrode formed on the second base substrate, and a second vertical inorganic alignment layer formed on the pixel electrode; and
interposing a liquid crystal layer between the first display substrate and the second display substrate,
wherein the first and second vertical inorganic alignment layer have a resistivity of about 10¹⁰ohms-cm to about 10¹⁵ ohms-cm and a vertical aligning property.

9. The method of claim 8, wherein the first display substrate is formed by:
applying a plasma power to a plasma generating member attached to an outside of a reactor;
loading the first base substrate into the reactor, on which the common electrode is formed and to which a back-bias voltage and heat are applied;
injecting a reaction gas into the reactor; and
controlling a frequency of the plasma power to form the first vertical inorganic alignment layer onto the process substrate.

10. The method of claim 9, wherein the plasma power has a frequency of about 10¹ Hz to about 10⁵ Hz.

11. The method of claim 8, wherein the second display substrate is formed by:
applying a plasma power to a plasma generating member attached to an outside of a reactor;
loading the first base substrate into the reactor, on which the pixel electrode is formed and to which a back-bias voltage and heat are applied;
injecting a reaction gas into the reactor; and
controlling a frequency of the plasma power to form the second vertical inorganic alignment layer onto the process substrate.

12. The method of claim 11, wherein the plasma power has a frequency of about 10¹ Hz to about 10⁵ Hz.

13. The method of claim 11, wherein the second vertical inorganic alignment layer comprises a silicon oxide layer (SiOx).

14. A liquid crystal display comprising:
a first display substrate having a first base substrate, a common electrode formed on the first base substrate, and a first vertical inorganic alignment layer formed on the common electrode;
a second display substrate having a second base substrate, a pixel electrode formed on the second base substrate, and a second vertical inorganic alignment layer formed on the pixel electrode; and
a liquid crystal layer interposed between the first display substrate and the second display substrate,
wherein the first and second vertical inorganic alignment layer have a resistivity of about 10¹⁰ ohms-cm to about 10¹⁵ ohms-cm and a vertical aligning property.

15. The liquid crystal display of claim 14, wherein the first and second vertical inorganic alignment layers have a silicon oxide layer (SiOx).

16. The liquid crystal display of claim 14, wherein the common electrode is provided with a plurality of first openings formed therethrough, and the pixel electrode is provided with a plurality of second openings formed therethrough and positioned between the first openings.
